(19) United States
(12) Patent Application Publication
(10) Pub. No.: US 2026/0304979 A1
(43) Pub. Date: Oct. 1, 2026

(54) PIXEL ARRAY OF IMAGE SENSOR

(71) Applicant: SAMSUNG ELECTRONICS CO., LTD., Suwon-si (KR)

(72) Inventors: Seungki Baek, Suwon-si (KR); Sungmin An, Suwon-si (KR)

(73) Assignee: SAMSUNG ELECTRONICS CO., LTD., Suwon-si (KR)

(21) Appl. No.: 19/538,479

(22) Filed: Feb. 12, 2026

(30) Foreign Application Priority Data
Mar. 28, 2025 (KR) 10-2025-0040369

(51) Int. Cl. H10F 39/00

(52) U.S. Cl. CPC H10F 39/8053

(57) ABSTRACT

A pixel array of an image sensor includes an inter-pixel trench structure, first and second photoelectric conversion regions, and an intra-pixel trench structure. The inter-pixel trench structure is provided in a semiconductor substrate to divide the semiconductor substrate into a plurality of pixel regions. The inter-pixel trench structure extends in a first horizontal direction and a second horizontal direction and has a lattice shape. The first and second photoelectric conversion regions are provided in a pixel region. The intra-pixel trench structure is provided in the plurality of pixel regions to isolate the first photoelectric conversion region and the second photoelectric conversion region. The inter-pixel trench structure has a first thickness, and at least a portion of the intra-pixel trench structure has a second thickness greater than the first thickness.

### CROSS-REFERENCE TO RELATED APPLICATION

This U.S. non-provisional application is based on and claims priority under 35 USC § 119 to Korean Patent Application No. 10-2025-0040369, filed on Mar. 28, 2025, in the Korean Intellectual Property Office (KIPO), the disclosure of which is incorporated by reference herein in its entirety.

### BACKGROUND

### 1. Field

Example embodiments relate generally to semiconductor integrated circuits, and more particularly to a pixel array of an image sensor.

### 2. Description of the Related Art

Complementary metal oxide semiconductor (CMOS) image sensors are solid-state sensing devices or may include solid-state sensing devices that use complementary metal oxide semiconductors. CMOS image sensors have lower manufacturing costs and/or lower power consumption compared with charge-coupled device (CCD) image sensors. Thus CMOS image sensors are used for various electronic appliances including portable devices such as, for example, smartphones and/or digital cameras.

A pixel array included in a CMOS image sensor may include a photoelectric conversion element such as a photodiode in each pixel. The photoelectric conversion element generates an electrical signal that varies based on the quantity of incident light. The CMOS image sensor processes electrical signals to synthesize an image. With the recent proliferation of high-resolution images, pixels included in the CMOS image sensor are becoming much smaller. When the pixels get smaller, incident light may not be properly sensed and/or noise may occur due to interference between highly integrated elements. Alternatively or additionally, the CMOS image sensor is expected to have enhanced image quality and to perform additional functions such as auto focusing.

### SUMMARY

Some example embodiments may provide a pixel array of an image sensor having enhanced sensing capability.

According to an aspect of the disclosure, there is provided a pixel array of an image sensor, including: a substrate including an inter-pixel trench structure configured to divide the semiconductor substrate into a plurality of pixel regions, the inter-pixel trench structure including first portions extending in a first horizontal direction and second portions extending in a second horizontal direction perpendicular to the first horizontal direction and having a lattice shape when viewed in a vertical direction; a first photoelectric conversion region and a second photoelectric conversion region in a first pixel region of the plurality of pixel regions; and an intra-pixel trench structure in the first pixel region, the intra-pixel trench structure configured to separate the first photoelectric conversion region and the second photoelectric conversion region from each other, wherein the inter-pixel trench structure has a first thickness, and at least a portion of the intra-pixel trench structure has a second thickness greater than the first thickness.

According to another aspect of the disclosure, there is provided a pixel array of an image sensor, including: a substrate including an inter-pixel trench structure configured to divide the semiconductor substrate into a plurality of pixel regions, the inter-pixel trench structure including first portions extending in a first horizontal direction and second portions extending in a second horizontal direction perpendicular to the first horizontal direction and having a lattice shape when viewed in a vertical direction; a first photoelectric conversion region, a second photoelectric conversion region, a third photoelectric conversion region and a fourth photoelectric conversion region in a first pixel region of the plurality of pixel regions; and an intra-pixel trench structure in the first pixel region, the intra-pixel trench structure configured to separate isolate the first photoelectric conversion region, the second photoelectric conversion region, the third photoelectric conversion region and the fourth photoelectric conversion region from each other, wherein the inter-pixel trench structure has a first thickness, and at least a portion of the intra-pixel trench structure has a second thickness greater than the first thickness.

According to another aspect of the disclosure, there is provided a pixel array of an image sensor, including: a substrate including an inter-pixel trench structure in a semiconductor to divide the semiconductor substrate into a plurality of pixel regions, the inter-pixel trench structure including first portions extending in a first horizontal direction and second portions extending in a second horizontal direction perpendicular to the first horizontal direction and having a lattice shape when viewed in a vertical direction; a plurality of photoelectric conversion regions in a first pixel region of the plurality of pixel regions; and an intra-pixel trench structure in the first pixel region, the intra-pixel trench structure configured to separate the plurality of photoelectric conversion regions from each other, wherein the inter-pixel trench structure has a first thickness, and at least a portion of the intra-pixel trench structure has a second thickness greater than the first thickness.

The pixel array of the image sensor according to example embodiments may increase the full well capacity and at the same time increase the charge overflow barrier between the photoelectric conversion regions in the pixel region, by setting the second thickness of the intra-pixel trench structure being relatively greater than the first thickness of the inter-pixel trench structure.

### BRIEF DESCRIPTION OF DRAWINGS

Example embodiments of the disclosure will be more clearly understood from the following detailed description taken in conjunction with the accompanying drawings.

FIG. 1 is a plan view illustrating a layout of a pixel array of an image sensor according to example embodiments.

FIG. 2 is a block diagram illustrating an image sensor according to example embodiments.

FIG. 3 is a circuit diagram illustrating an example of a unit circuit included in an image sensor according to example embodiments.

FIG. 4 is a timing diagram illustrating an example operation of an image sensor according to example embodiments.

FIG. 5 is a plan view illustrating an example embodiment of a pixel included in a pixel array of an image sensor according to example embodiments.

FIGS. 6, 7 and 8 are cross-sectional views illustrating example embodiments of vertical structures of pixels included in a pixel array of an image sensor according to example embodiments.

FIG. 9 is a circuit diagram illustrating a configuration corresponding to the pixel of FIG. 5 and a read circuit.

FIG. 10 is a plan view illustrating an example embodiment of a pixel included in a pixel array of an image sensor according to example embodiments.

FIGS. 11, 12 and 13 are cross-sectional views illustrating example embodiments of vertical structures of pixels included in a pixel array of an image sensor according to example embodiments.

FIGS. 14, 15, 16, 17 and 18 are plan views illustrating example embodiments of a pixel included in a pixel array of an image sensor according to example embodiments.

FIG. 19 is a plan view illustrating an example embodiment of a pixel included in a pixel array of an image sensor according to example embodiments.

FIG. 20 is a circuit diagram illustrating a configuration corresponding to the pixel of FIG. 19 and a read circuit.

FIG. 21 is a plan view illustrating a layout of a pixel array included in an image sensor according to example embodiments.

FIGS. 22, 23 and 24 are plan views illustrating example embodiments of an arrangement pattern of a pixel array included in image sensors according to example embodiments.

FIG. 25 is a block diagram illustrating an electronic device according to example embodiments.

FIG. 26 is a block diagram illustrating a camera module included in the electronic device of FIG. 25.

### DETAILED DESCRIPTION

Various example embodiments will be described more fully hereinafter with reference to the accompanying drawings, in which some example embodiments are shown. In the drawings, like numerals refer to like elements throughout. The repeated descriptions may be omitted.

Hereinafter, two directions parallel to and intersecting the surfaces of the semiconductor substrate may be defined as a first horizontal direction DR1 and a second horizontal direction DR2, respectively, and a direction substantially perpendicular to the surfaces of the semiconductor substrate may be defined as a vertical direction DR3. The first horizontal direction DR1 may correspond to a row direction and the second horizontal direction DR2 may correspond to a column direction.

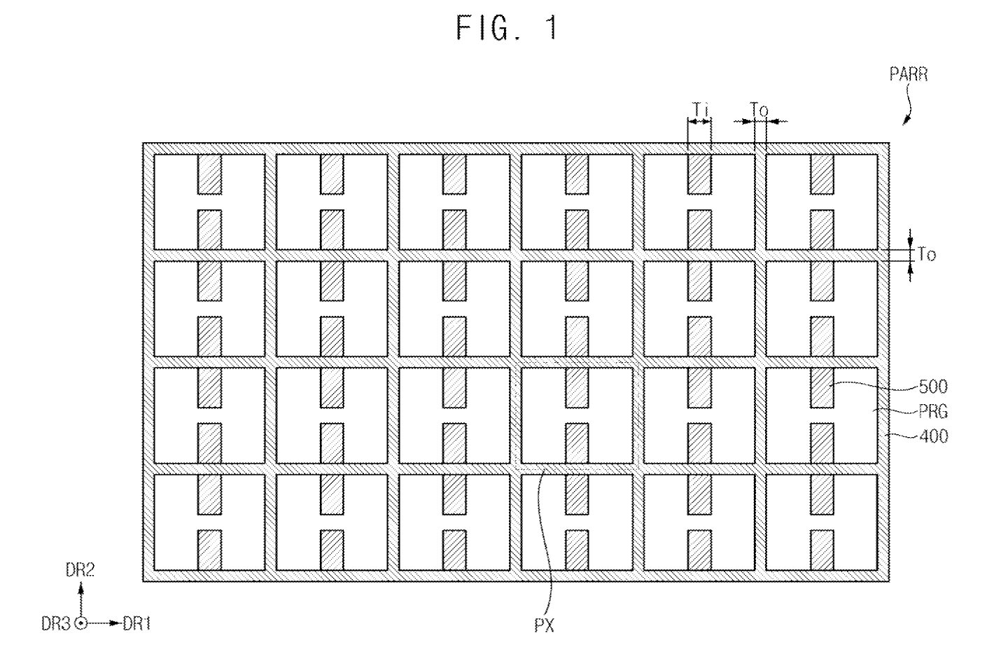

FIG. 1 is a plan view illustrating a layout of a pixel array of an image sensor according to example embodiments.

For convenience of illustration and description, only trench structures for describing example embodiments are illustrated in FIG. 1. The pixel array of the image sensor may further include components such as a photoelectric conversion region, a floating diffusion region, a transfer gate, and a readout circuit. The more specific configurations and operations of the pixel array and pixels will be described below.

Referring to FIG. 1, a pixel array PARR of an image sensor may include an inter-pixel trench structure 400 and an intra-pixel trench structure 500.

The inter-pixel trench structure 400 is formed in a semiconductor substrate. For example, the inter-pixel trench structure 400 is formed to divide the semiconductor substrate into a plurality of pixel regions PRG. For example, the inter-pixel trench structure 400 may separate of isolate the plurality of pixel regions PRG from each other. As illustrated in FIG. 1, the inter-pixel trench structure 400 extends in a first horizontal direction DR1 and a second horizontal direction DR2 perpendicular to the first horizontal direction DR1 and has a lattice shape when viewed in a vertical direction DR3. For example, the inter-pixel trench structure 400 include first portions that extend in a first horizontal direction DR1 and second portions that extent in a second horizontal direction DR2 perpendicular to the first horizontal direction DR1.

As will be described below, a plurality of photoelectric conversion regions may be formed in each pixel region PRG of the plurality of pixel regions PRG.

The intra-pixel trench structure 500 is formed in the plurality of pixel regions PRG. For example, the pixel trench structure 500 may separate or isolate the plurality of photoelectric conversion regions included in each pixel region PRG. As a result, the pixel array PARR may be formed such that that a plurality of pixels PX may be repeatedly arranged in the first horizontal direction DR1 and the second horizontal direction DR2.

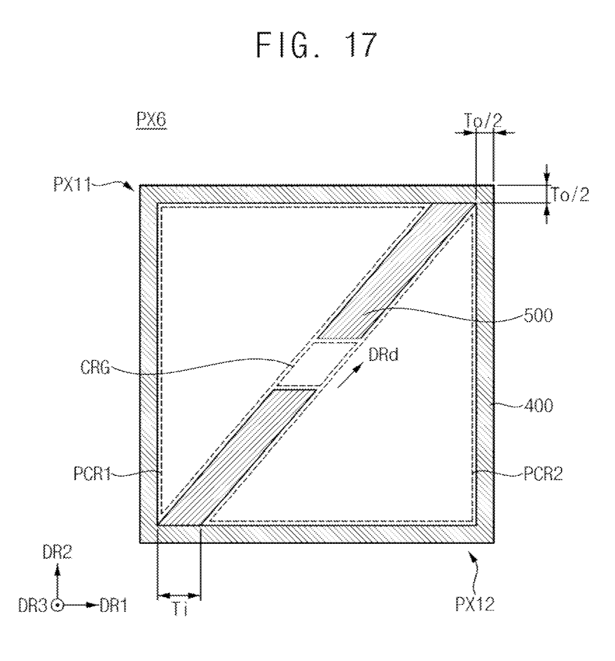

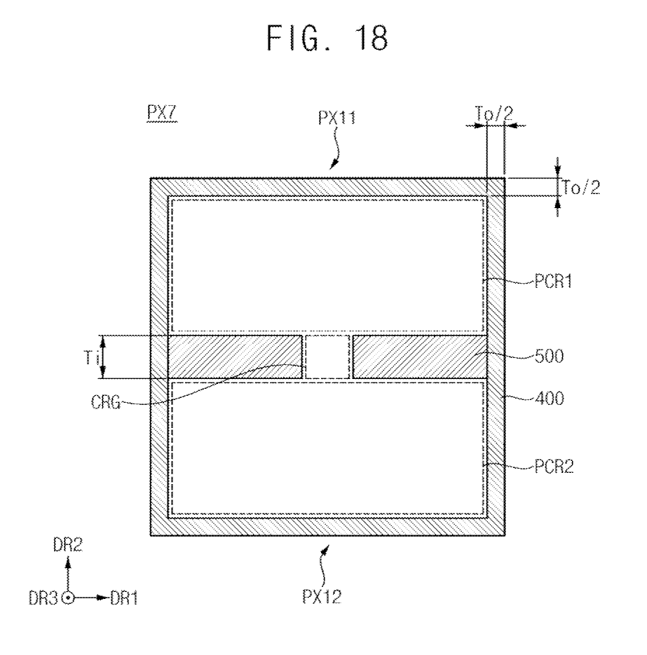

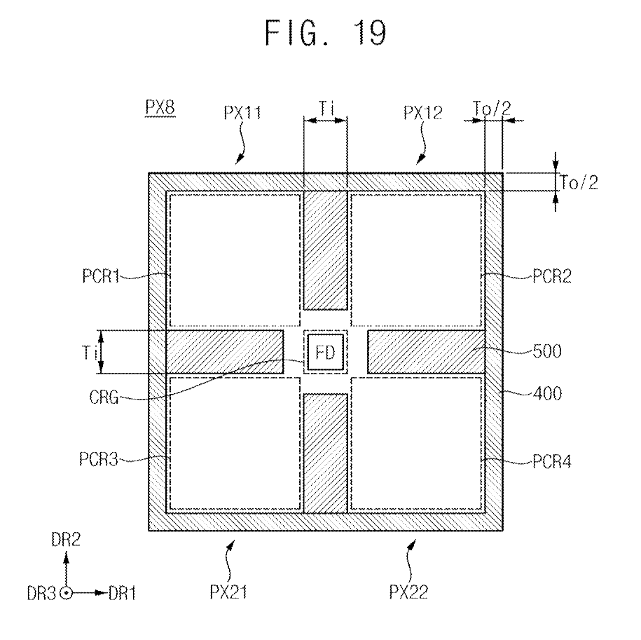

In an example embodiment, as illustrated in FIG. 1, the intra-pixel trench structure 500 may be formed to divide each pixel region PRG into two equal portions. In this case, each pixel region PRG may include two photoelectric conversion regions that are formed one by one in two sub-pixel regions corresponding to the two equal portions of each pixel region PRG. Although FIG. 1 illustrates an example in which each pixel region PRG is divided into two equal portions, the disclosure is not limited thereto. As such, according to another embodiment, the intra-pixel trench structure 500 may be formed to divide each pixel region PRG such that the pixel regions PRG may not have equal portions. Although FIG. 1 illustrates an example embodiment in which the intra-pixel trench structure 500 extends in the second horizontal direction DR2, example embodiments are not limited thereto. According to example embodiments, as will be described below with reference to FIG. 17, the intra-pixel trench structure 500 may extend in the diagonal horizontal direction DRd, and as will be described below with reference to FIG. 18, the intra-pixel trench structure 500 may extend in the first horizontal direction DR1. In an example embodiment, as will be described below with reference to FIG. 19, the intra-pixel trench structure 500 may be formed to divide each pixel region into four equal portions. In this case, each pixel region PRG may include four photoelectric conversion regions that are formed one by one in four sub-pixel regions corresponding to the four equal portions of each pixel region PRG. According to example embodiments, the inter-pixel trench structure 400 has a first thickness To, and at least a portion of the intra-pixel trench structure 500 has a second thickness Ti greater than the first thickness To. In this disclosure, the "thickness of the trench" refers to the "size of the trench in the direction orthogonal to the direction in which the trench extends when viewed from the vertical direction DR3.

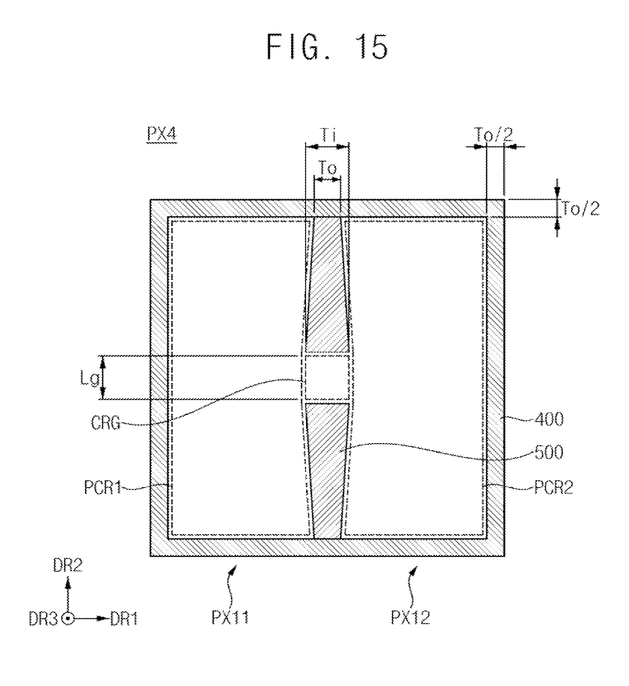

Although FIG. 1 illustrates an example of a rectangular shape in which the intra-pixel trench structure 500 has a uniform second thickness Ti, example embodiments are not limited thereto. According to the example embodiments, the intra-pixel trench structure 500 may be implemented in various shapes as will be described below with reference to FIGS. 14 and 15.

In related art method, a same CD (critical dimension) is applied to the inter-pixel trench structure 400 and the intra-pixel trench structure 500 to form the thicknesses of the inter-pixel trench structure 400 and the intra-pixel trench structure 500 to be the same. When all thicknesses of the inter-pixel trench structure 400 and the intra-pixel trench structure 500 are reduced to the first thickness To, the area of the pixel region PRG may increase, which may increase the full well capacity (FWC), but the charge overflow barrier (COB) (i.e., the potential barrier), between the photoelectric conversion regions formed in each pixel region PRG is lowered, which reduces the sensing sensitivity of each photoelectric conversion region.

The pixel array of the image sensor according to the example embodiments may increase the full well capacity of the pixel PX including a plurality of photoelectric conversion regions by setting the first thickness To of the inter-pixel trench structure 400 to be relatively small and setting the second thickness Ti of the intra-pixel trench structure 500 to be relatively large, while increasing the charge overflow barrier between the photoelectric conversion regions included in each pixel PX. That is, the sensing range of the pixel may be increased while increasing the sensing sensitivity of each photoelectric conversion region, thereby improving the auto-focusing performance.

The thickness and the shape of the trenches may be controlled by changing the mask pattern of the etching process for the trench structures during the manufacturing process of the pixel array, and example embodiments may be implemented efficiently without excessively changing an existing manufacturing process.

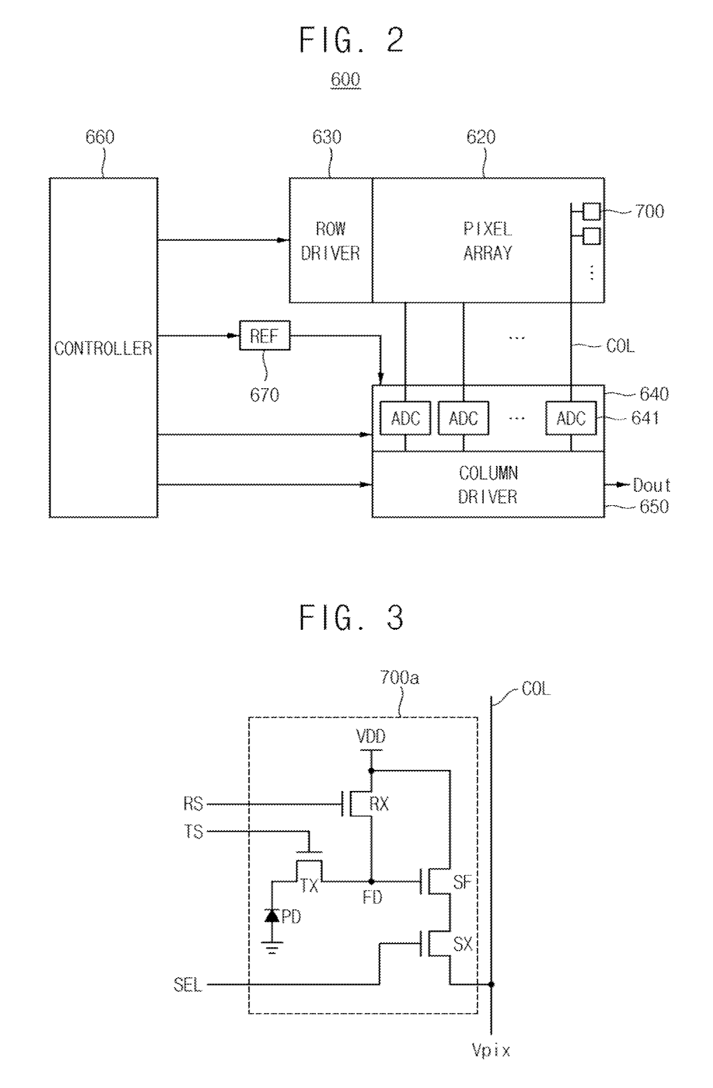

Hereinafter, the configuration and operation of the image sensor to which the example embodiments may be applied will be described with reference to FIGS. 2, 3 and 4.

FIG. 2 is a block diagram illustrating an image sensor according to example embodiments.

Referring to FIG. 2, an image sensor 600 may include a pixel array 620, a row driver 630, an analog-to-digital conversion circuit 640, a column driver 650, a controller 660, and/or a reference signal generator REF 670. The image sensor 600 may include one or more other components.

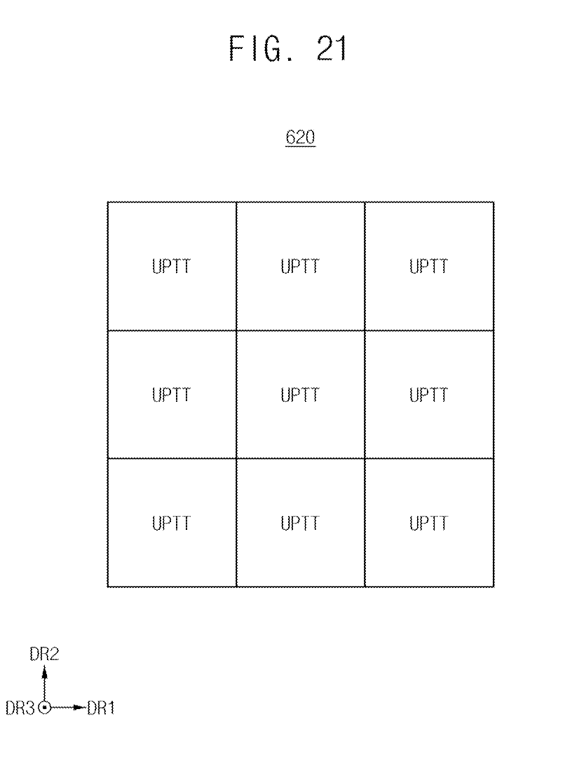

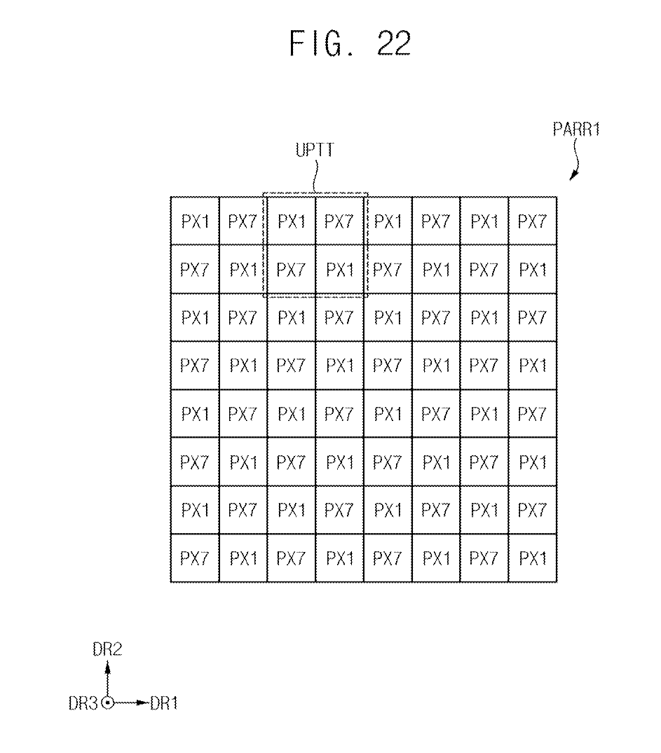

The pixel array 620 includes a plurality of pixels 700 coupled to column lines COL, respectively, and the plurality of pixels 700 senses incident light to generate analog signals through the column lines COL. The plurality of pixels 700 may be arranged in matrix form with a plurality of rows and a plurality of columns. The matrix may be a rectangular matrix or a square matrix. The pixel array 620 may have a structure that various unit patterns, which will be described below with reference to FIGS. 21 through 24, are arranged repeatedly in the first horizontal direction DR1 and the second horizontal direction DR2.

The row driver 630 may be coupled to the rows of the pixel array 620 to generate signals for driving the rows. For example, the row driver 630 may drive the pixels in the pixel array 620 row by row.

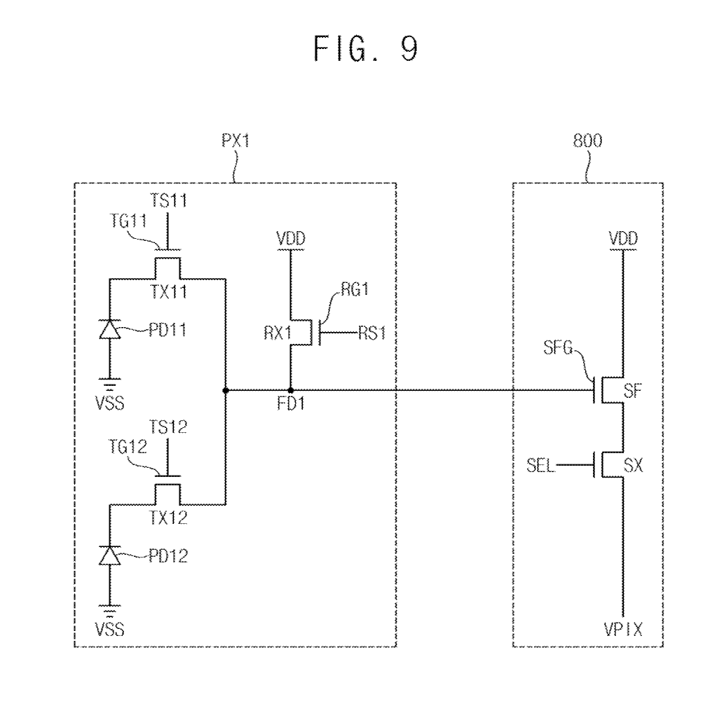

The analog-to-digital conversion circuit 640 may be coupled to the columns of the pixel array 620 to convert the analog signals from the pixel array 20 to digital signals. As illustrated in FIG. 9, the analog-to-digital conversion circuit 640 may include a plurality of analog-to-digital converters (ADC) 641 to perform analog-to-digital conversion of the analog signals output from the column lines COL in parallel or simultaneously.

The analog-to-digital conversion circuit 640 may include a correlated double sampling (CDS) unit. In some example embodiments, the CDS unit may perform an analog double sampling by extracting a valid image component based on a difference between an analog reset signal and an analog image signal. Alternatively or additionally, in some example embodiments, the CDS unit may perform a digital double sampling by converting the analog reset signal and the analog image signal to two digital signals and extracting a difference between the two digital signals as the valid image component. Alternatively or additionally, in some example embodiments, the CDS unit may perform a dual CDS by performing both the analog double sampling and digital double sampling.

The column driver 650 may output the digital signals from the analog-to-digital conversion circuit 40 sequentially as output data Dout.

The controller 660 may control the row driver 30, the analog-to-digital conversion circuit 640, the column driver 650, and/or the reference signal generator 670. The controller 660 may provide control signals such as clock signals, timing control signals, etc. to control and/or facilitate the operations of the row driver 630, the analog-to-digital conversion circuit 640, the column driver 650, and/or the reference signal generator 670. The controller 660 may include one or more of a control logic circuit, a phase-locked loop, a timing control circuit, a communication interface circuit, etc.

The reference signal generator 670 may generate a reference signal or a ramp signal that increases or decreases gradually and provide the ramp signal to the analog-to-digital conversion circuit 40.

FIG. 3 is a circuit diagram illustrating an example of a unit circuit included in an image sensor according to example embodiments.

Referring to FIG. 3, a unit pixel 700a may include a photo-sensitive element such as a photodiode PD, and a readout circuit including a transfer transistor TX, a reset transistor RX, a source follower transistor SF and/or a selection transistor SX.

For example, the photodiode PD may include an n-type region in a p-type substrate such that the n-type region and the p-type substrate form a p-n conjunction diode. The photodiode PD receives the incident light and generates a photo-charge based on the incident light. In some example embodiments, the unit pixel 600a may include a phototransistor, a photogate, and/or a pinned photodiode, etc. instead of, or in addition to, the photodiode PD.

The photo-charge generated in the photodiode PD may be transferred to a floating diffusion node FD through the transfer transistor TX. The transfer transistor TG may be turned on based on a transfer control signal TS. The transfer transistor TX may be turned on in response to a transfer control signal TS.

The source follower transistor SF may function as a source follower amplifier that amplifies a signal corresponding to the charge on the floating diffusion node FD. The selection transistor SEL may transfer the pixel signal Vpix to a column line COL based on a selection signal SEL. The selection transistor SX may transfer the pixel signal Vpix to a column line COL in response to a selection signal SEL. In some example embodiments, the source follower transistor SF may also be referred to as a drive transistor.

The floating diffusion node FD may be reset by the reset transistor RX. For example, the reset transistor RG may discharge the floating diffusion node FD based on a reset signal RS for correlated double sampling (CDS). For example, the reset transistor RG may discharge the floating diffusion node FD in response to a reset signal RS for correlated double sampling (CDS).

FIG. 3 illustrates the unit pixel 700a of the four-transistor configuration including the four transistors TX, RX, SF and SX. The configuration of the unit pixel may be variously changed and the pixel structure is not limited to that of FIG. 3.

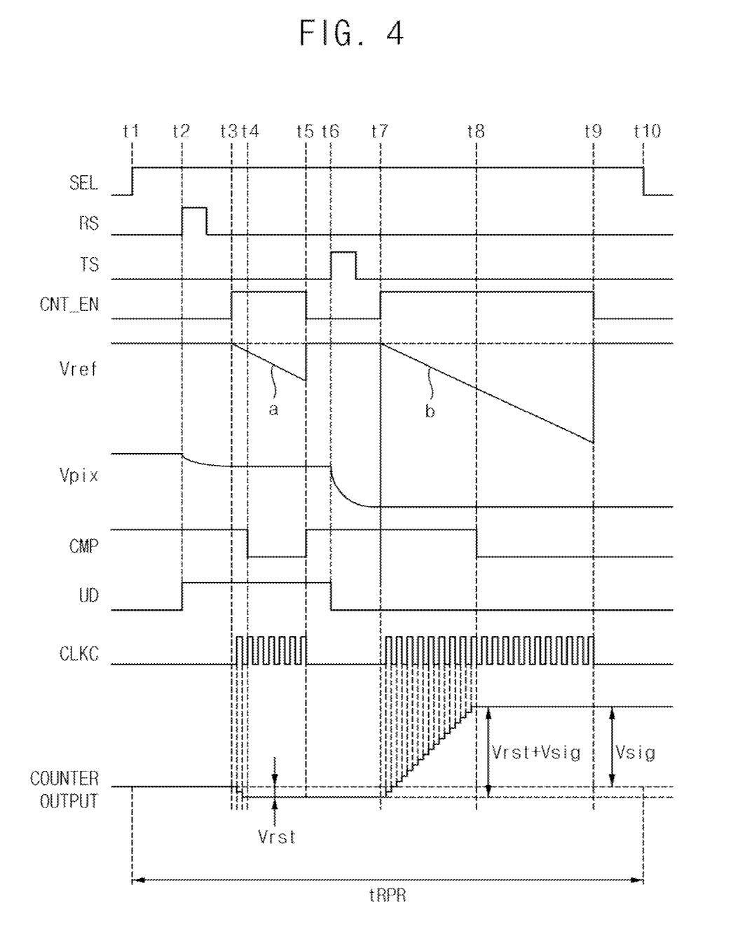

FIG. 4 is a timing diagram illustrating an example operation of an image sensor according to example embodiments.

FIG. 4 illustrates a sensing period tRPR corresponding to a sensing operation of a pixel. The sensing operation may be performed simultaneously with respect to pixels corresponding to the same transfer control signal TS.

Referring to FIGS. 2, 3 and 4, at a time t1, the row driver 630 may select one of rows included in the pixel array 20 by providing an activated row selection signal SEL to the selected row of the pixel array 620.

At a time t2, the row driver 630 may provide an activated reset control signal RS to the selected row, and the controller 60 may provide an up-down control signal UD having a logic high level to a counter included in the ADC 641. From the time t2, the pixel array 620 may output a first analog signal corresponding to a reset component Vrst as the pixel voltage Vpix.

At a time t3, the controller 660 may provide a count enable signal CNT_EN having a logic high level to the reference signal generator 670, and the reference signal generator 670 may start to decrease the reference signal Vref at the constant rate, e.g., a slope of ‘a’. The controller 660 may provide a count clock signal CLKC to the counter, and the counters may perform down-counting from zero in synchronization with the count clock signal CLKC.

At a time t4, a magnitude of the reference signal Vref may become smaller than a magnitude of the pixel voltage Vpix, and a comparator included in the ADC 641 may provide a comparison signal CMP having a logic low level to the counter so that the counter stops performing the down-counting. At the time t4, a counter output of the counter may be the first counting value that corresponds to the reset component Vrst. In the example of FIG. 4, the counter output of the counter at the time t4 may be -2.

At a time t5, the controller 660 may provide the count enable signal CNT_EN having a logic low level to the reference signal generator 670, and the reference signal generator 670 may stop generating the reference signal Vref.

A period from the time t3 to the time t5 corresponds to a maximum time for detecting the reset component Vrst. A length of the period from the time t3 to the time t5 may be determined as a certain number of the count clock signal CLKC according to a characteristic of the image sensor 700.

At a time t6, the row driver 630 may provide an activated transfer control signal TS to the selected row, and the controller 660 may provide the up-down control signal UD having a logic low level to the counter. For example, the transfer control signal TS has a logic high level. From the time t6, the pixel array 620 may output a second analog signal AS2 corresponding to a detected incident light Vrst+Vsig as the pixel voltage Vpix.

At a time t7, the controller 660 may provide the count enable signal CNT_EN having a logic high level to the reference signal generator 670, and the reference signal generator 670 may start to decrease the reference signal Vref at the same constant rate as at the time t3, e.g., a slope of ‘b’. The comparator may provide the comparison signal CMP having a logic high level to the counter since the pixel voltage Vpix is smaller than the reference signal Vref. The controller 660 may provide the count clock signal CLKC to the counter, and the counter may perform an up-counting from the first counting value, which corresponds to the reset component Vrst, in synchronization with the count clock signal CLKC.

At a time t8, the magnitude of the reference signal Vref may become smaller than the magnitude of the pixel voltage Vpix, and the comparator may provide the comparison signal CMP having a logic low level to the counter so that the counter stops performing the up-counting. At the time t8, the counter output of the counter may correspond to a difference between the first analog signal representing the reset component Vrst (e.g., -2 in the example of FIG. 4) and the second analog signal representing the detected incident light Vrst+Vsig (e.g., 17 in the example of FIG. 4). The difference may be an effective intensity of incident light Vsig (e.g., 15 in the example of FIG. 4). The counter may output the effective intensity of incident light Vsig as the digital signal.

At a time t9, the controller 660 may provide the count enable signal CNT_EN having a logic low level to the reference signal generator 670, and the reference signal generator 670 may stop generating the reference voltage Vref.

A period from the time t7 to the time t9 corresponds to a maximum time for detecting the detected incident light Vrst+Vsig. A length of the period from the time t7 to the time t9 may be determined as a certain number of the count clock signal CLKC according to a characteristic of the image sensor 700.

At a time t10, the row driver 630 may provide a deactivated row selection signal SEL to the selected row of the pixel array 620, and the counter may reset the counter output to zero. For example, the row selection signal has a low level.

After that, the image sensor 700 may repeat above described operations on each row to generate the digital signals row by row.

Example embodiments are not limited to the example configuration and operation described with reference to FIGS. 2, 3 and 4.

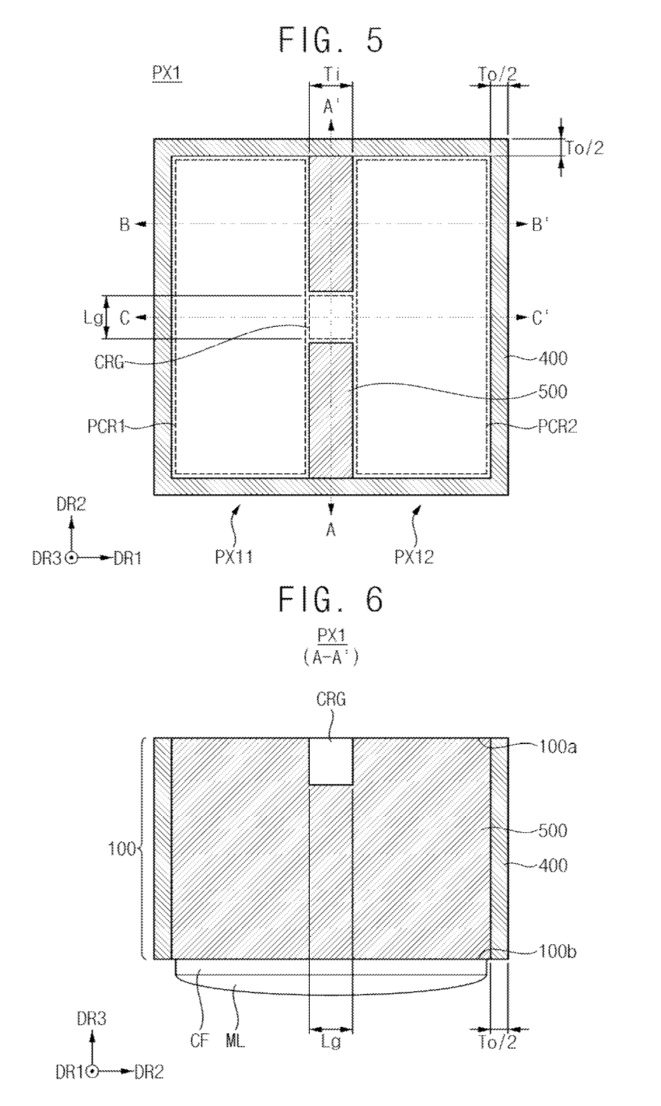

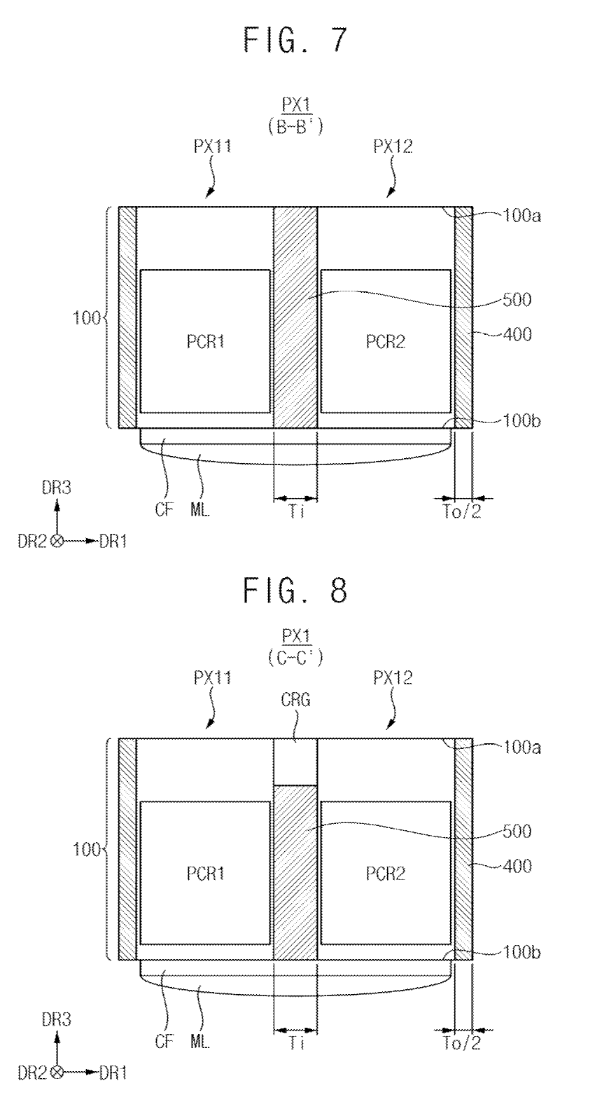

FIG. 5 is a plan view illustrating an example embodiment of a pixel included in a pixel array of an image sensor according to example embodiments, and FIGS. 6, 7 and 8 are cross-sectional views illustrating example embodiments of vertical structures of pixels included in a pixel array of an image sensor according to example embodiments. FIG. 6 is a cross-sectional view taken along a line A-A' of FIGS. 5, 7 is a cross-sectional view taken along a line B-B' of FIGS. 5 and 8, is a cross-sectional view taken along a line C-C' of FIG. 5.

Referring to FIGS. 5 through 8, a pixel PX1 may include a first sub-pixel region PX11 and a second sub-pixel region PX12. The first sub-pixel region PX11 may include a first photoelectric conversion region PCR1, and the second sub-pixel region PX12 may include a second photoelectric conversion region PCR2. The trench structures 400 and 500 may be arranged in the semiconductor substrate 100 and extend in the vertical direction DR3 from the front surface 100a to the back surface 100b of the semiconductor substrate 100 to electrically and optically isolate the photoelectric conversion regions PCR1 and PCR2 that are included respectively in the first sub-pixel region PX11 and the second sub-pixel region PX12.

The trench structures 400 and 500 may include the inter-pixel trench structure 400 that isolates each pixel PX1 and adjacent pixels, and the intra-pixel trench structure 500 that isolates the first sub-pixel region PX11 and the second sub-pixel region PX12 included in each pixel PX1 from each other.

The inter-pixel trench structures 400 may extend in the vertical direction DR3 from the front surface 100a to the back surface 100b of the semiconductor substrate 100 to surround the periphery of the first sub-pixel region PX11 and the second sub-pixel region PX12.

The intra-pixel trench structure 500 may prevent incident light and photocharges generated by the incident light from being transferred between the first photoelectric conversion region PCR1 and the second photoelectric conversion region PCR2 included in the first sub-pixel region PX11 and the second sub-pixel region PX12, respectively. That is, the intra-pixel trench structure 500 may prevent a crosstalk phenomenon between the photoelectric conversion regions PCR1 and PCR2. In addition, the inter-pixel trench structure 400 may prevent crosstalk phenomenon between each pixel PX1 and adjacent pixels.

As illustrated in FIGS. 5 through 8, the intra-pixel trench structure 500 may extend in the second horizontal direction DR2 to divide the pixel region (PRG of FIG. 1) of the pixel PX1 into two equal portions, a first sub-pixel region PX11 and a second sub-pixel region PX12. The cross region CRG may be formed in the central portion of the intra-pixel trench structure 500 in the second horizontal direction DR2. The intra-pixel trench structure 500 may be implemented in a rectangular shape having a uniform second thickness Ti. A portion corresponding to the cross region CRG of the intra-pixel trench structure 500 for transferring charges between the first photoelectric conversion region PCR1 and the second photoelectric conversion region PCR2 may be removed at least partially in the vertical direction DR3 from the front surface 100a of the semiconductor substrate 100. In an example embodiment, as illustrated in FIGS. 5 through 8, only a portion of the central portion corresponding to the cross region CRG of the intra-pixel trench structure 500 may be removed in the vertical direction DR3 from the front surface 100a to the back surface 100b of the semiconductor substrate 100. Electrons may pass between sub-pixel regions through the cross region CRG, and the charge transfer may be controlled based on the potential profile formed in the semiconductor substrate 100 according to the manufacturing process by the second thickness Ti, the removed length Lg, and the removed depth of the intra-pixel trench structure 500. The second thickness Ti corresponds to the size of the cross region CRG in the first horizontal direction DR1, the removed length Lg corresponds to the size of the cross region CRG in the second horizontal direction DR2, and the removed depth corresponds to the size of the cross region CRG in the vertical direction DR3.

In an example embodiment, as illustrated in FIGS. 5 through 8, the first photoelectric conversion region PCR1 and the second photoelectric conversion region PCR2 may be formed in the first sub-pixel region PX11 and the second sub-pixel region PX12 of the semiconductor substrate 100, respectively. For example, when the semiconductor substrate 100 has a P-type conductivity, the photoelectric conversion regions PCR1 and PCR2 may have an N-type conductivity.

According to example embodiments, the semiconductor substrate 100 includes a plurality of regions that are doped with impurities of different concentrations and/or different conductivity types and are distinguished from each other. For example, when the semiconductor substrate 100 has a P-type conductivity, the semiconductor substrate 100 may include an N- region, a P- region, and a P+ region sequentially from the top. The P- region indicates that it is doped with an impurity of the opposite conductivity type to the N- region, and the P+ region has a higher impurity concentration than the P- region. Incident photons penetrate into the P- region and generate electron-hole pairs. That is, the P- region may correspond to a main photocharge generation region. The photoelectrons as the generated minority carriers may move to the depletion region of the N-P junction (N-P conjunction) corresponding to the boundary of the N-region and the P-region. At this time, since the P+ region with a higher impurity concentration is located below the P-region, the photoelectrons generated near the boundary of the P-region and the P+ region tend to move to the N-P junction region (N-P conjunction portion). According to the example embodiment, the N-region may be replaced with the P region.

A color filter layer CF and a microlens ML may be arranged on the back surface 100b of the semiconductor substrate 100. One color filter layer CF and one microlens ML may be arranged on the first subpixel region PX11 and the second subpixel region PX12 included in one pixel PX1.

The pixel array may include a color filter array such that the pixels may sense various colors. In an example embodiment, the color filter layer CF may be one of the filters that sense red (R), green (G), and blue (B), and the color filter layer CF may be arranged to correspond to a Bayer pattern, and example embodiments are not limited to a particular color filter array. The pixel array 110 according to the example embodiment may include various types of color filters, and for example, the color filters may include filters for sensing yellow, cyan, and magenta colors.

Gate structures such as a transfer gate and a reset gate may be arranged on the front surface 100a of the semiconductor substrate 100. In addition, a plurality of interlayer insulating films and wiring structures may be further arranged on the front surface 100a of the semiconductor substrate 100. The wiring structures may be for connecting transistors arranged in the first sub-pixel region PX11 and the second sub-pixel region PX12.

According to example embodiments, the inter-pixel trench structure 400 has the first thickness To, and at least a portion of the intra-pixel trench structure 500 has the second thickness Ti greater than the first thickness To. As illustrated in FIGS. 5 through 8, a portion corresponding to half the thickness (To/2) of the first thickness To of the inter-pixel trench structure 400 may be considered to belong to the pixel PX1. That is, a portion corresponding to the remaining half the thickness (To/2) of the first thickness To of the inter-pixel trench structure 400 may be considered to belong to pixels neighboring the pixel PX1. As illustrated in FIGS. 5 through 8, the first sub-pixel region PX11 and the second sub-pixel region PX12 share one microlens CMLS, and the pixel PX1 may be a two-photodiode (2PD) pixel for auto-focusing.

FIG. 9 is a circuit diagram illustrating a configuration corresponding to the pixel of FIG. 1 and a read circuit 800. Hereinafter, descriptions overlapping with FIGS. 1 through 8 are omitted.

Referring to FIG. 9, a pixel PX1 may include a floating diffusion region FD1, a first photodiode PD11 and a first transfer transistor TX11 of a first sub-pixel region PX11, a second photodiode PD12 and a second transfer transistor TX12 of a second sub-pixel region PX12, and a reset transistor RX1. The first sub-pixel region PX11, the second sub-pixel region PX12, and the reset transistor RX1 are commonly connected to the floating diffusion region FD1.

Control signals TS11, TS12 and RS1 provided to gates TG11, TG12 and RG1 of the pixel PX1 may be transferred from the row driver 630 of FIG. 2 through the wirings in the row direction (e.g., the first horizontal direction DR1).

The reset transistor RX1 is connected between a reset voltage, for example, a power supply voltage VDD and the floating diffusion region FD1, and may be switched based on the reset signal RS1. For example, the reset transistor RX1 may be switched in response to the reset signal RS1.

For convenience of illustration, the transfer gates TG11 and TG12, the reset gate RG1, the floating diffusion region FD1, the gate SFG of the source follower transistor SF, and the selection transistor SX are omitted in FIGS. 5 through 8. The omitted components may be placed in an appropriate location in the boundary area between the pixels or inside the pixel.

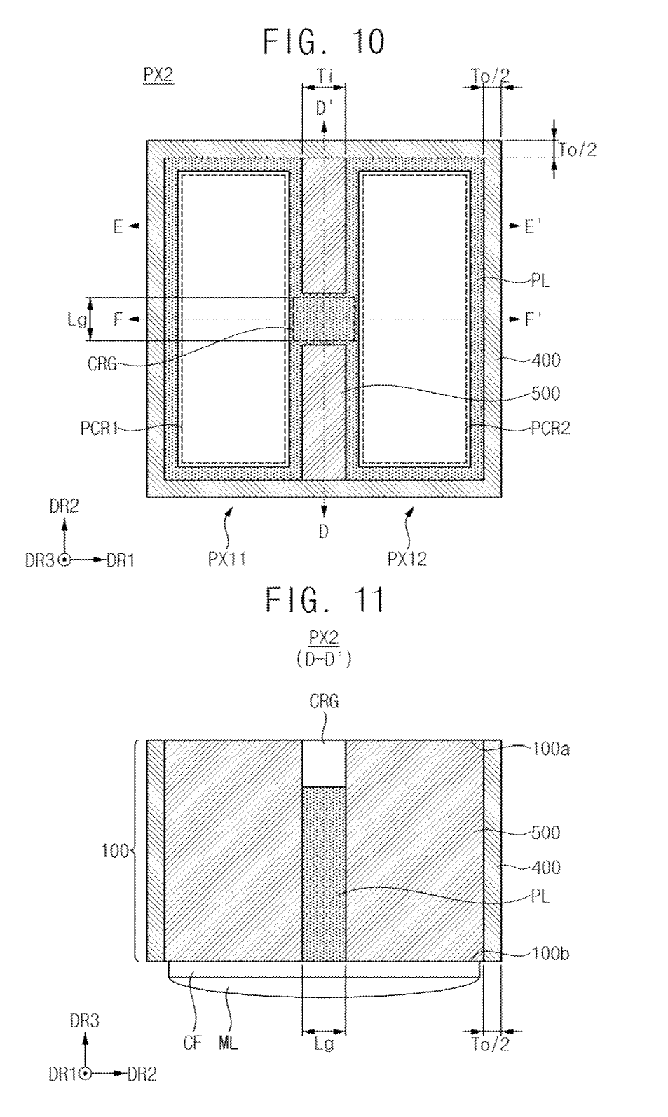

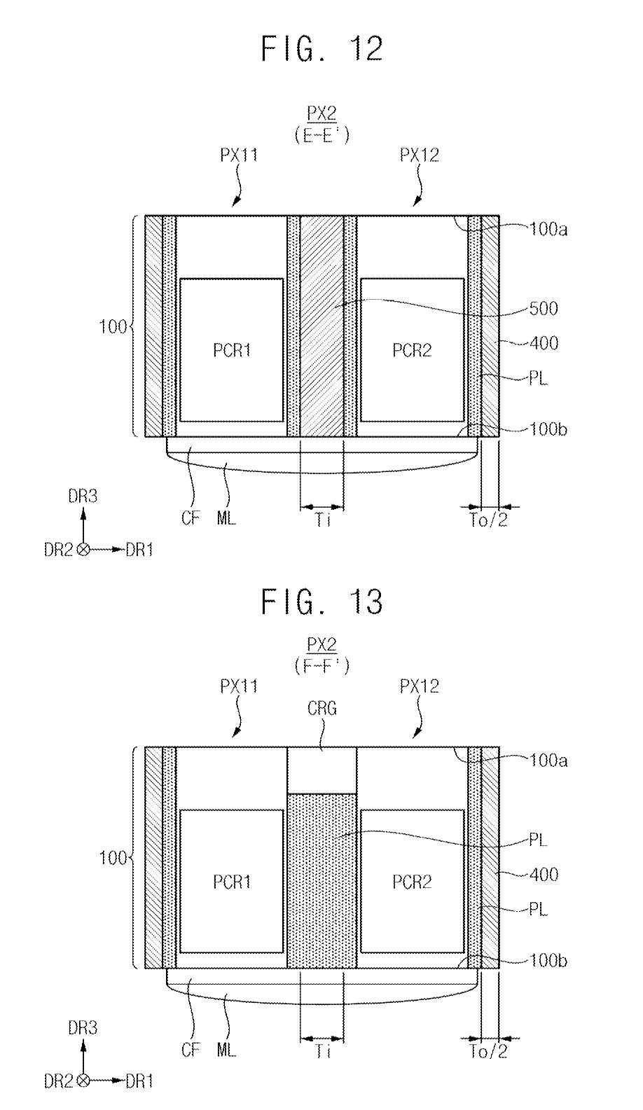

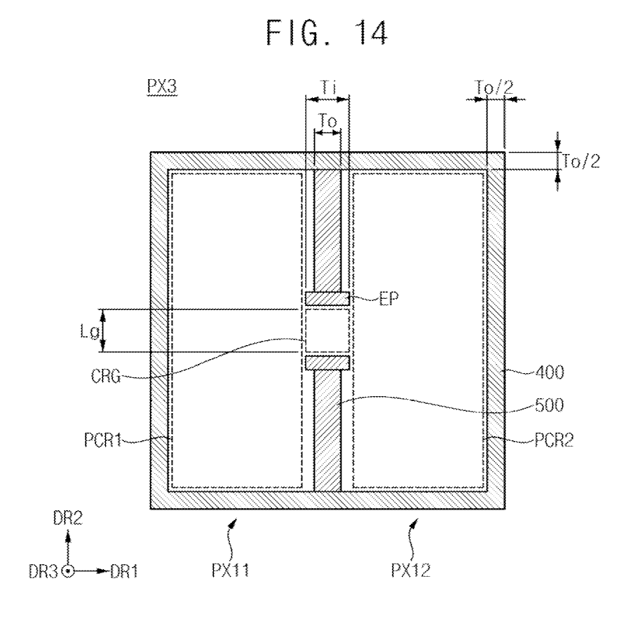

FIG. 10 is a plan view illustrating an example embodiment of a pixel included in a pixel array of an image sensor, and FIGS. 11, 12 and 13 are cross-sectional views illustrating example embodiments of vertical structures of pixels included in a pixel array of an image sensor. FIG. 11 is a cross-sectional view taken along a line D-D' of FIG. 10, FIG. 12 is a cross-sectional view taken along a line E-E' of FIGS. 10 and 13 is a cross-sectional view taken along a line F-F' of FIG. 10. The description overlapping with FIGS. 5 through 8 are omitted.

Referring to FIGS. 10 through 13, a pixel PX2 may include a first sub-pixel region PX11 and a second sub-pixel region PX12. The first sub-pixel region PX11 may include a first photoelectric conversion region PCR1, and the second sub-pixel region PX12 may include a second photoelectric conversion region PCR2.

As shown in FIGS. 10 through 13, the intra-pixel trench structure 500 may extend in the second horizontal direction DR2 to divide the pixel region (PRG of FIG. 1) of the pixel PX2 into two equal portions, that is, the first sub-pixel region PX11 and a second sub-pixel region PX12. The cross region CRG may be formed in the central portion of the intra-pixel trench structure 500 in the second horizontal direction DR2. The intra-pixel trench structure 500 may be implemented in a rectangular shape having a uniform second thickness Ti.

The pixel PX2 may further include a passivation film PL. The passivation film PL may be formed to surround the inter-pixel trench structure 400 and the intra-pixel trench structure 500. The passivation film PL may also be formed to surround the first sub-pixel region PX11 and may be formed to surround the second sub-pixel region PX12. The passivation film PL may be provided between the first sub-pixel region PX11 and the second sub-pixel region PX12. In an example embodiment, the passivation film PL may include silicon doped with a first conductivity type, for example, p-type.

A portion corresponding to the cross region CRG of the intra-pixel trench structure 500 for transferring charges between the first photoelectric conversion region PCR1 and the second photoelectric conversion region PCR2 may be removed at least in a vertical direction DR3 from the front surface 100a of the semiconductor substrate 100.

In an example embodiment, as illustrated in FIGS. 10 to 13, a central portion corresponding to a cross region CRG of an intra-pixel trench structure 500 may be completely removed in a vertical direction DR3 from the front surface 100a to the back surface 100b of the semiconductor substrate 100. A passivation film PL may also be formed in the removed portion of the intra-pixel trench structure 500. For example, the passivation film PL may be formed in a portion corresponding to the cross region CRG. In the portion corresponding to the cross region CRG, the passivation film PL may extend in a vertical direction DR3 from the back surface 100b of the semiconductor substrate 100 to a specific depth. That is, as illustrated in FIGS. 11 and 13, a portion of the passivation film PL may extend in a vertical direction DR3 from a lower portion of the cross region CRG to the back surface 100b of the semiconductor substrate 100.

The depth of the passivation film PL in the cross region CRG corresponding to the size in the vertical direction DR3 of the cross region CRG may be varied. In an example embodiment, the depth of the passivation film PL may be reduced by implanting ions of a second conductivity type (e.g., n-type) opposite to the first conductivity type into the front surface 100a of the semiconductor substrate 100. Alternatively, in an example embodiment, the depth of the passivation film PL may be increased by implanting ions of the first conductivity type. The passivation film PL may provide a potential barrier between the first photoelectric conversion region PCR1 and the second photoelectric conversion region PCR2 by having a conductivity type opposite to that of the first photoelectric conversion region PCR1 and the second photoelectric conversion region PCR2. That is, a potential well may be formed between the first photoelectric conversion region PCR1 and the second photoelectric conversion region PCR2 by the passivation film PL, and the linearity of the full well of the first sup-pixel region PX11 and the second sub-pixel region PX12 may be improved.

According to example embodiments, the inter-pixel trench structure 400 has the first thickness To, and at least a portion of the intra-pixel trench structure 500 has the second thickness Ti greater than the first thickness To. As illustrated in FIGS. 10 to 13, a portion corresponding to a thickness (To/2) of half of the first thickness To of the inter-pixel trench structure 400 may be considered to belong to the pixel PX2. That is, a portion corresponding to the remaining half thickness (To/2) of the first thickness To of the inter-pixel trench structure 400 may be considered to belong to pixels neighboring the pixel PX2.

As illustrated in FIGS. 10 through 13, the first sub-pixel region PX11 and the second sub-pixel region PX12 share one microlens CMLS, and the pixel PX2 may be a 2PD (two-photodiode) pixel for auto-focusing.

FIGS. 14 through 18 are plan views illustrating example embodiments of a pixel included in a pixel array of an image sensor according to example embodiments. Hereinafter, descriptions overlapping with those of FIGS. 5 through 8 are omitted, and differences from the pixel PX1 of FIGS. 5 through 8 will be described.

Referring to FIG. 14, the intra-pixel trench structure 500 included in a pixel PX3 may have a hammer shape in which an end portion EP adjacent to the cross region CRG protrudes to have a second thickness Ti and the remaining portion except for the end portion EP adjacent to the cross region CRG has a thickness (for example, a first thickness To) smaller than the second thickness Ti. Compared to the pixel PX1 of FIG. 5, the pixel PX3 of FIG. 14 may further increase the area of the pixel region PRG and increase the full well capacity.

Referring to FIG. 15, the intra-pixel trench structure 500 included in a pixel PX4 may have a rhombus shape in which an end portion EP adjacent to the cross region CRG has a second thickness Ti and the thickness of the remaining portion excluding the end portion EP gradually decreases as the remaining portion is farther away from the cross region CRG. Compared to the pixel PX1 of FIG. 5, the pixel PX4 of FIG. 15 may further increase the full well capacity by increasing the pixel region PRG. In addition, compared to the pixel PX3 of FIG. 14, the pixel PX4 of FIG. 15 has a simple etching pattern for forming the intra-pixel trench structure 500, which is advantageous for the CD (critical dimension) constraints in the manufacturing process.

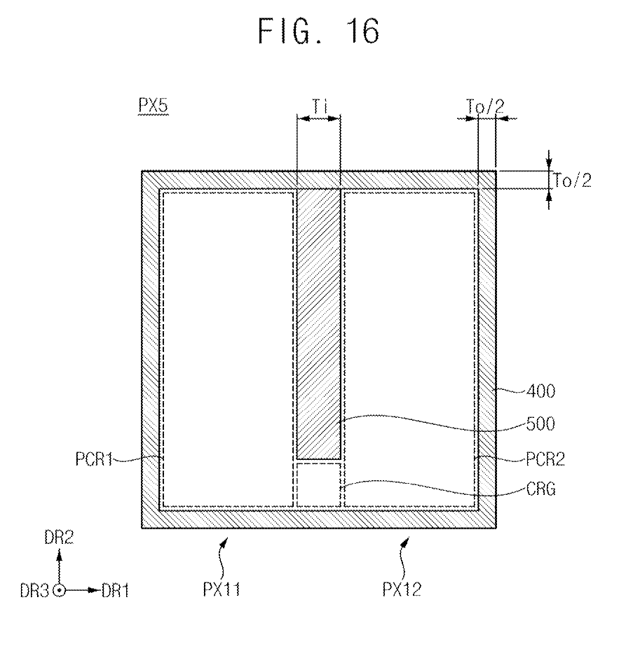

Referring to FIG. 16, the cross region CRG of a pixel PX5 may be formed adjacent to the inter-pixel trench structure 400 at the end of the intra-pixel trench structure 500 in the second horizontal direction DR2.

Referring to FIG. 17, the intra-pixel trench structure 500 included in a pixel PX6 may extend in a diagonal direction DRd between the first horizontal direction DR1 and the second horizontal direction DR2 to divide the pixel region into two equal portions, that is, a first sub-pixel region PX11 and a second sub-pixel region PX12. The cross region CRG of the pixel PX6 may be formed in the central portion of the intra-pixel trench structure 500 in the diagonal horizontal direction DRd. While the pixel PX1 of FIG. 5 is for auto-focusing in the first horizontal direction DR1, the pixel PX6 of FIG. 17 may be used for both of auto-focusing in the first horizontal direction DR1 and auto-focusing in the second horizontal direction DR2. However, the disclosure is not limited thereto, and as such, the intra-pixel trench structure 500 may be provide in any other arrangement to divide the pixel region into two equal portions.

Referring to FIG. 18, the intra-pixel trench structure 500 of a pixel PX7 may extend in the first horizontal direction DR1 to divide the pixel region (PRG of FIG. 1) of the pixel PX7 into two equal portions, that is, a first sub-pixel region PX11 and a second sub-pixel region PX12. The cross region CRG may be formed in the central portion of the intra-pixel trench structure 500 in the first horizontal direction DR1. The intra-pixel trench structure 500 may be implemented in a rectangular shape having a uniform second thickness Ti. While the pixel PX1 of FIG. 5 is for auto-focusing in the first horizontal direction DR1, the pixel PX7 of FIG. 18 may be used for auto-focusing in the second horizontal direction DR2.

FIG. 19 is a plan view illustrating an example embodiment of a pixel included in a pixel array of an image sensor according to example embodiments. Hereinafter, descriptions overlapping with FIGS. 5 through 8 are omitted.

Referring to FIG. 19, a pixel PX8 may include a first sub-pixel region PX11, a second sub-pixel region PX12, a third sub-pixel region PX21, and a fourth sub-pixel region PX22. The first sub-pixel region PX11 may include a first photoelectric conversion region PCR1, the second sub-pixel region PX12 may include a second photoelectric conversion region PCR2, the third sub-pixel region PX21 may include a third photoelectric conversion region PCR3, and the fourth sub-pixel region PX22 may include a fourth photoelectric conversion region PCR4. Trench structures 400 and 500 may be arranged in the semiconductor substrate 100 and extend in the vertical direction DR3 from the front surface 100a to the back surface 100b of the semiconductor substrate 100 to electrically and optically isolate the photoelectric conversion regions PCR1, PCR2, PCR3 and PCR4 respectively included in the first sub-pixel region PX11, the second sub-pixel region PX12, the third sub-pixel region PX21, and the fourth sub-pixel region PX22.

The trench structures 400 and 500 may include an inter-pixel trench structure 400 that isolates each pixel PX8 and adjacent pixels, and an intra-pixel trench structure 500 that isolates the first sub-pixel region PX11, the second sub-pixel region PX12, the third sub-pixel region PX21, and the fourth sub-pixel region PX22 included in each pixel PX8 from each other.

The inter-pixel trench structures 400 may extend in the vertical direction DR3 from the front surface 100a to the back surface 100b of the semiconductor substrate 100 to surround the periphery of the first sub-pixel region PX11, the second sub-pixel region PX12, the third sub-pixel region PX21, and the fourth sub-pixel region PX22.

The intra-pixel trench structure 500 may include a first intra-pixel trench structure extending in the second horizontal direction DR2 to divide the pixel region into two equal portions in the first horizontal direction DR1 and a second intra-pixel trench structure extending in the first horizontal direction DR1 to divide the pixel region into two equal portions in the second horizontal direction DR2. As a result, the first intra-pixel trench structure and the second intra-pixel trench structure may divide the pixel region into four equal portions, as illustrated in FIG. 19. The cross region CRG may be formed at a portion where the first intra-pixel trench structure and the second intra-pixel trench structure intersect. For example, the cross region CRG may be formed at a central portion of the pixel region. According to example embodiments, a floating diffusion region FD shared by the first photoelectric conversion region PCR1, the second photoelectric conversion region PCR2, the third photoelectric conversion region PCR3, and the fourth photoelectric conversion region PCR4 may be formed in the cross region CRG.

The intra-pixel trench structure 500 may prevent incident light and photocharges generated by the incident light from being transferred between the photoelectric conversion regions PCR1, PCR2, PCR3 and PCR4. That is, the intra-pixel trench structure 500 may prevent a crosstalk phenomenon between the photoelectric conversion regions PCR1, PCR2, PCR3 and PCR4. In addition, the inter-pixel trench structure 400 may prevent crosstalk phenomenon between each pixel PX8 and adjacent pixels.

According to example embodiments, the inter-pixel trench structure 400 has the first thickness To, and at least a portion of the intra-pixel trench structure 500 has the second thickness Ti greater than the first thickness To.

The first sub-pixel region PX11, the second sub-pixel region PX12, the third sub-pixel region PX21, and the second sub-pixel region PX22 of FIG. 19 share one microlens ML, and the pixel PX8 may be a 4PD (four-photodiode) pixel for auto-focusing in the first horizontal direction DR1 and the second horizontal direction DR2.

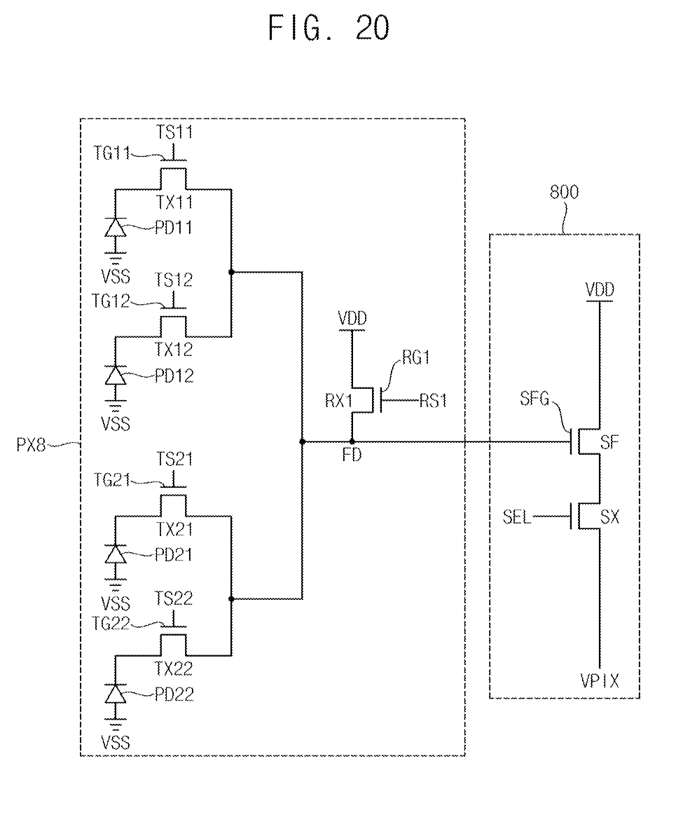

FIG. 20 is a circuit diagram illustrating a configuration corresponding to the pixel of FIG. 19 and a read circuit 800.

Referring to FIG. 20, the pixel PX8 may include a floating diffusion region FD, a first photodiode PD11 and a first transfer transistor TX11 of a first sub-pixel region PX11, a second photodiode PD12 and a second transfer transistor TX12 of a second sub-pixel region PX12, a third photodiode PD21 and a third transfer transistor TX21 of a third sub-pixel region PX21, a fourth photodiode PD22 and a fourth transfer transistor TX22 of a fourth sub-pixel region PX22, and a reset transistor RX1. The first sub-pixel region PX11, the second sub-pixel region PX12, the third sub-pixel region PX21, and the fourth sub-pixel region PX22 and the reset transistor RX1 are commonly connected to the floating diffusion region FD.

Control signals TS11, TS12, TS21, TS22, and RS1 provided to the gates TG11, TG12, TG21, TG22, and RG1 of the pixel PX8 may be transferred from the row driver 630 of FIG. 2 through wires extending in the row direction (e.g., the first horizontal direction DR1).

The reset transistor RX1 is connected between a reset voltage, for example, a power supply voltage VDD, and the floating diffusion region FD, and may be switched based on the reset signal RS1. For example, the reset transistor RX1 may be switched in response to the reset signal RS1.

FIG. 21 is a plan view illustrating a layout of a pixel array included in an image sensor according to example embodiments.

Referring to FIG. 21, the pixel array 620 included in the image sensor 600 of FIG. 2 may be divided into unit patterns UPTT that are repeatedly arranged in the first horizontal direction DR1 and the second horizontal direction DR2 perpendicular to the first horizontal direction DR1. The unit patterns UPTT may include pixel groups that include one or more pixels including two sub-pixel regions and/or four sub-pixel regions as described above.

In an example embodiment, the unit patterns UPTT may all be the same. In this case, each unit pattern UPTT corresponds to a minimum unit pattern that cannot be divided into smaller units. In another example embodiment, the unit patterns UPTT may include two or more different patterns, and the different patterns may be regularly arranged in the first horizontal direction DR1 and/or the second horizontal direction DR2.

In an example embodiment, each of the pixels PX1 through PX8 described with reference to FIGS. 5 through 20 may form the unit patterns UPTT. In another example embodiment, a combination of two or more different pixels may form the unit patterns UPTT, as will be described below with reference to FIGS. 22 through 24.

Hereinafter, example embodiments of unit patterns corresponding to various different pixel groups will be described with reference to FIGS. 22 through 24. For convenience of illustration, according to the example embodiments, the pixel arrays described below may be inverted in the first horizontal direction DR1 and/or the second horizontal direction DR2, or may be rotated 90 degrees or 180 degrees around the vertical direction DR3.

FIGS. 22, 23 and 24 are plan views illustrating example embodiments of an arrangement pattern of a pixel array included in image sensors according to example embodiments.

Referring to FIGS. 22, 23 and 24, the pixels PX1 of FIG. 5 that perform auto-focusing in the first horizontal direction DR1 and the pixels PX7 of FIG. 18 that perform auto-focusing in the second horizontal direction DR2 may be arranged variously. The pixels PX1 of FIG. 5 include the first pixel regions in which the intra-pixel trench structure 500 extends in the second horizontal direction DR2 to divide each pixel region into two equal portions in the first horizontal direction DR1. The pixels PX7 of FIG. 18 include the second pixel regions in which an intra-pixel trench structure 500 extends in the first horizontal direction DR1 to divide each pixel region into two equal portions in the second horizontal direction DR2.

In an example embodiment, the unit patterns UPTT of a pixel array PARR1 of FIG. 22 may include two pixels PX1 arranged adjacently in one diagonal direction and two pixels PX7 arranged adjacently in another diagonal direction.

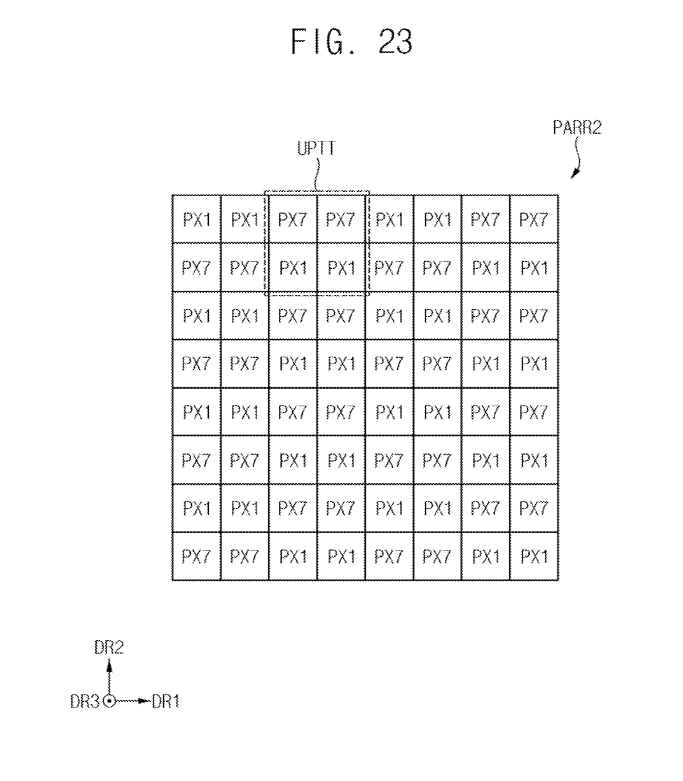

In an example embodiment, the unit patterns UPTT of a pixel array PARR2 of FIG. 23 may include two pixels PX1 arranged adjacently in the first horizontal direction DR1 and two pixels PX7 arranged adjacently in the first horizontal direction DR1.

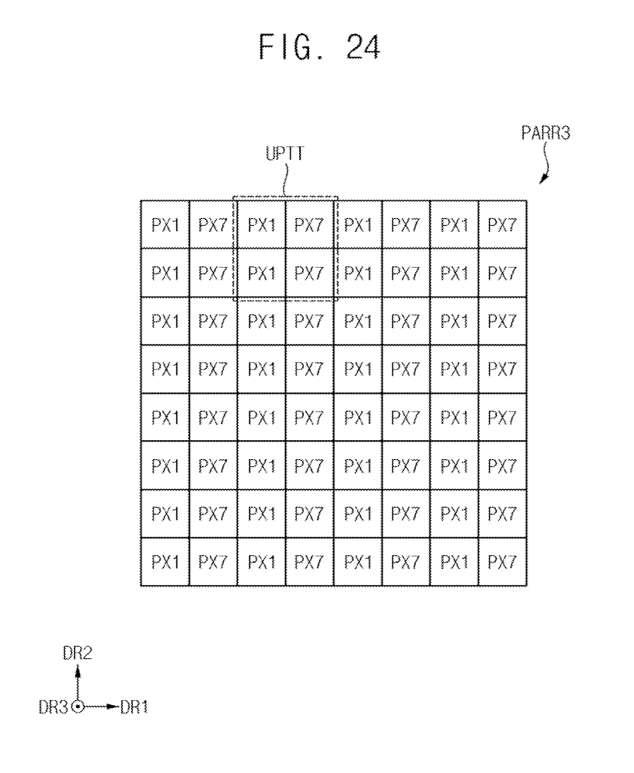

In an example embodiment, the unit pattern UPTT of a pixel array PARR3 of FIG. 24 may include two pixels PX1 arranged adjacently in the second horizontal direction DR2 and two pixels PX7 arranged adjacently in the second horizontal direction DR2.

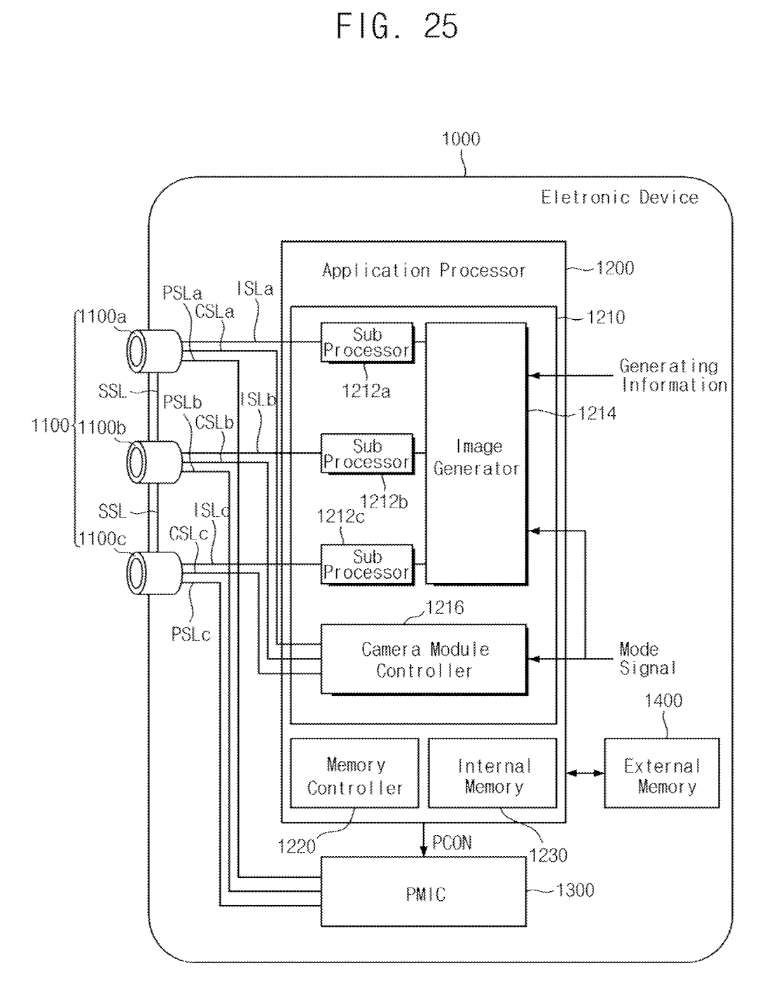

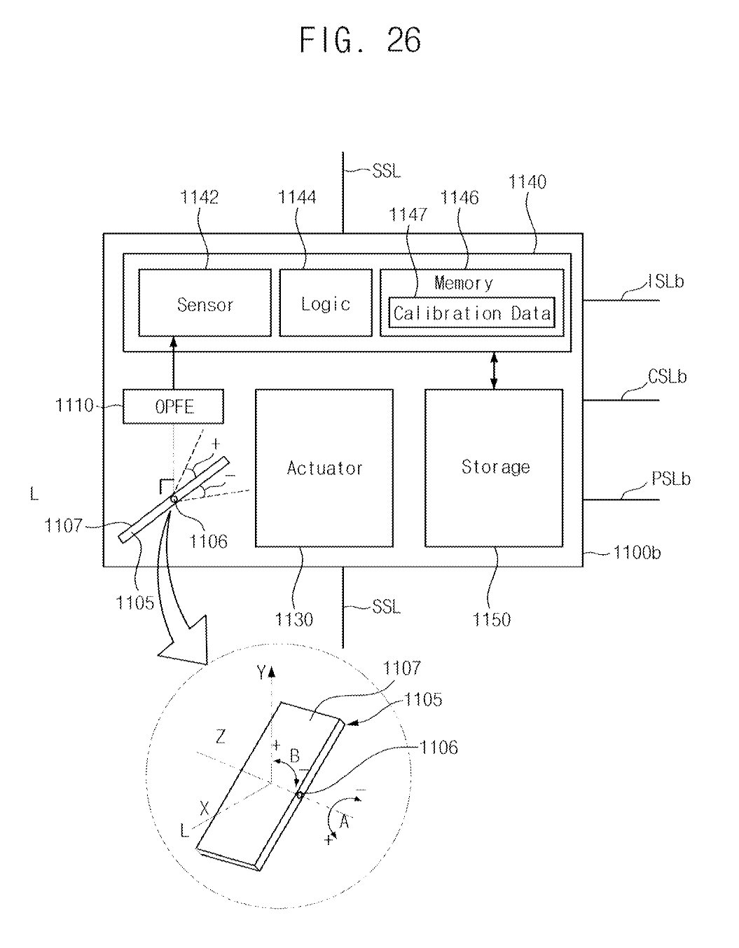

FIG. 25 is a block diagram illustrating an electronic device according to example embodiments, and FIG. 26 is a block diagram illustrating a camera module included in the electronic device of FIG. 25.

Referring to FIG. 25, an electronic device 1000 may include a camera module group 1100, and application processor 1200, a power management integrated circuit (PMIC) 1300 and/or an external memory 1400.

The camera module group 1100 may include a plurality of camera modules 1100a, 1100b and 1100c. FIG. 25 illustrates the three camera modules 1100a, 1100b and 1100c as an example, but example embodiments are not limited to a particular number of camera modules. According to example embodiments, the camera module group 1100 may include two camera modules, and four or more camera modules.

Hereinafter, an example configuration of the camera module 1100b is described with reference to FIG. 26. According to example embodiments, the same descriptions may be applied to the other camera modules 1100a and 1100c.

Referring to FIG. 26, the camera module 1100b may include a prism 1105, an optical path folding element (OPFE) 1110, an actuator 1130, an image sensing device 1140 and a storage device 1150.

The prism 1105 may include a reflection surface 1107 to change a path of a light L incident on the prism 1105.

In some example embodiments, the prism 1105 may change the path of the light L incident in a first direction X to the path in a second direction Y perpendicular to the first direction X. In addition, the prism 1105 may rotate the reflection surface 1107 around a center axis 1106 and/or rotate the center axis 1106 in the B direction to align the path of the reflected light along the second direction Y. In addition, the OPFE 1110 may move in a third direction perpendicular to the first direction X and the second direction Y.

In some example embodiments, a rotation angle of the prism 1105 may be smaller than 15 degrees in the positive (+) A direction and greater than 15 degrees in the negative (-) A direction, but example embodiments are not limited thereto.

In some example embodiments, the prism 1105 may rotate within 20 degrees in the positive B direction and the negative B direction.

In some example embodiments, the prism 1105 may move the reflection surface 1106 in the third direction Z that is in parallel with the center axis 1106.

The OPFE 1110 may include optical lenses that are divided into m groups where m is a positive integer. The m lens group may move in the second direction Y to change an optical zoom ratio of the camera module 1100b. For example, the optical zoom ratio may be changed in a range of 3K, 5K, and so on by moving the m lens group, when K is a basic optical zoom ratio of the camera module 1100b.

The actuator 1130 may move the OPFE 1110 or the optical lens to a specific position. For example, the actuator 1130 may adjust the position of the optical lens for accurate sensing such that an image sensor 1142 may be located at a position corresponding to a focal length of the optical lens.

The image sensing device 1140 may include the image sensor 1142, a control logic 1144 and/or a memory 1146. The image sensor 1142 may capture or sense an image using the light provided through the optical lens. The control logic 1144 may control overall operations of the camera module 1100b. For example, the control logic 1144 may provide control signals through control signal line CSLb to control the operation of the camera module 1100b.

The memory 1146 may store information such as calibration data 1147 for the operation of the camera module 1100b. For example, the calibration data 1147 may include information for generation of image data based on the provided light, such as information on the above-described rotation angle, a focal length, information on an optical axis, and so on. When the camera module 1100b is implemented as a multi-state camera having a variable focal length depending on the position of the optical lens, the calibration data 1147 may include multiple focal length values and auto-focusing values corresponding to the multiple states.

The storage device 1150 may store the image data sensed using the image sensor 1142. The storage device 1150 may be provided outside of the image sensing device 1140, and the storage device 1150 may be stacked with a sensor chip comprising the image sensing device 1140. The storage device 1150 may be implemented with an electrically erasable programmable read-only memory (EEPROM), but example embodiments are not limited thereto.

Referring to FIGS. 25 and 26, each of the camera modules 1100a, 1100b and 1100c may include the actuator 1130. In some example embodiments, the camera modules 1100a, 1100b and 1100c may include the same or different calibration data 1147 depending on the operations of the actuators 1130.

In some example embodiments, one camera module 1100b may have a folded lens structure included the above-described prism 1105 and the OPFE 1110, and the other camera modules 1100a and 1100b may have a vertical structure without the prism 1105 and the OPFE 1110.

In some example embodiments, one camera module 1100c may be a depth camera configured to measure distance information of an object using an infrared light. In some example embodiments, the application processor 1200 may merge the distance information provided from the depth camera 1100c and image data provided from the other camera modules 1100a and 1100b to generate a three-dimensional depth image.

In some example embodiments, at least two camera modules among the camera modules 1100a, 1100b and 1100c may have different field of views, for example, through different optical lenses.

In some example embodiments, each of the camera modules 1100a, 1100b and 1100c may be separated physically from each other. In other words, the camera modules 1100a, 1100b and 1100c may each include a dedicated image sensor 1142.

The application processor 1200 may include an image processing device 1210, a memory controller 1220 and an internal memory 1230. The application processor 1200 may be separated from the camera modules 1100a, 1100b and 1100c. For example, the application processor 1200 may be implemented as one chip and the camera modules 1100a, 1100b and 1100c may implemented as another chip or other chips.

The image processing device 1210 may include a plurality of sub processors 1212a, 1212b and 1212c, an image generator 1214 and a camera module controller 1216.

The image data generated by the camera modules 1100a, 1100b and 1100c may be provided to the sub processors 1212a, 1212b and 1212c through distinct image signal lines ISLa, ISLb and ISLc, respectively. For example, the transfer of the image data may be performed using a camera serial interface (CSI) based on the mobile industry processor interface (MIPI), but example embodiments are not limited thereto.

In some example embodiments, one sub processor may be assigned commonly to two or more camera modules. In some example embodiments, a multiplexer may be used to transfer the image data selectively from one of the camera modules to the shared sub processor.

The image data from the sub processors 1212a, 1212b and 1212c may be provided to the image generator 1214. The image generator 1214 may generate an output image using the image data from the sub processors 1212a, 1212b and 1212c according to image generating information or a mode signal. For example, the image generator 1213 may merge at least a portion of the image data from the camera modules 1100a, 1100b and 1100c having the different fields of view to generate the output image according to the image generating information or the mode signal. In addition, the image generator 1214 may select, as the output image, one of the image data from the camera modules 1100a, 1100b and 1100c according to the image generating information or the mode signal.

In some example embodiments, the image generating information may include a zoom factor or a zoom signal. In some example embodiments, the mode signal may be a signal based on a selection of a user.

When the image generating information is the zoom factor and the camera modules 1100a, 1100b and 1100c have the different field of views, the image generator 1214 may perform different operation depending on the zoom signal. For example, when the zoom signal is a first signal, the image generator 1214 may merge the image data from the different camera modules to generate the output image. When the zoom signal is a second signal different from the first signal, the image generator 1214 may select, as the output image, one of image data from the camera modules 1100a, 1100b and 1100c.

In some example embodiments, the image generator 1214 may receive the image data of different exposure times from the camera modules 1100a, 1100b and 1100c. In some example embodiments, the image generator 1214 may perform high dynamic range (HDR) processing with respect to the image data from the camera modules 1100a, 1100b and 1100c to generate the output image having the increased dynamic range.

The camera module controller 1216 may provide control signals to the camera modules 1100a, 1100b and 1100c. The control signals generated by the camera module controller 1216 may be provided to the camera modules 1100a, 1100b and 1100c through the distinct control signal lines CSLa, CSLb and CSLc, respectively.

In some example embodiments, one of the camera modules 1100a, 1100b and 1100c may be designated as a master camera according to the image generating information of the mode signal, and the other camera modules may be designated as slave cameras.

The camera module acting as the master camera may be changed according to the zoom factor or an operation mode signal. For example, when the camera module 1100a has the wider field of view than the camera module 1100b and the zoom factor indicates a lower zoom magnification, the camera module 1100b may be designated as the master camera. In contrast, when the zoom factor indicates a higher zoom magnification, the camera module 1100a may be designated as the master camera.

In some example embodiments, the control signals provided from the camera module controller 1216 may include a synch enable signal. For example, when the camera module 1100b is the master camera and the camera modules 1100a and 1100c are the slave cameras, the camera module controller 1216 may provide the synch enable signal to the camera module 1100b. The camera module 1100b may generate a synch signal based on the provided synch enable signal and provide the synch signal to the camera modules 1100a and 1100c through a synch signal line SSL. As such, the camera modules 1100a, 1100b and 1100c may transfer the synchronized image data to the application processor 1200 based on the synch signal.

In some example embodiments, the control signals provided from the camera module controller 1216 may include information on the operation mode. The camera modules 1100a, 1100b and 1100c may operate in a first operation mode or a second operation mode based on the information from the camera module controller 1216.

In the first operation mode, the camera modules 1100a, 1100b and 1100c may generate image signals with a first speed and encode the image signals with a second speed higher than the first speed to transfer the encoded image signals to the application processor 1200. For example, the camera modules 1100a, 1100b and 1100c may generate image signals with a first frame rate and encode the image signals with a second frame rate higher than the first frame rate. The second speed may be lower than thirty times the first speed. The application processor 1200 may store the encoded image signals in the internal memory 1230 or the external memory 1400. The application processor 1200 may read out and decode the encoded image signals to provide display data to a display device. For example, the sub processors 1212a, 1212b and 1212c may perform the decoding operation and the image generator 1214 may process the decoded image signals.

In the second operation mode, the camera modules 1100a, 1100b and 1100c may generate image signals with a third speed lower than the first speed to transfer the generated image signals to the application processor 1200. For example, the camera modules 1100a, 1100b and 1100c may generate image signals with a third frame rate lower than the first frame rate. In other words, the image signals that are not encoded may be provided to the application processor 1200. The application processor 1200 may process the received image signals or store the receive image signals in the internal memory 1230 or the external memory 1400.

The PMIC 1300 may provide a power supply voltage to the camera modules 1100a, 1100b and 1100c, respectively. For example, the PMIC 1300 may provide, under control of the application processor 1200, a first power to the camera module 1100a through a power line PSLa, a second power to the camera module 1100b through a power line PSLb, and a third power to the camera module 1100c through a power line PSLc.

The PMIC 1300 may generate the power respectively corresponding to the camera modules 1100a, 1100b and 1100c and control power levels, in response to a power control signal PCON from the application processor 1200. The power control signal PCON may include information on the power depending on the operation modes of the camera modules 1100a, 1100b and 1100c. For example, the operation modes may include a low power mode in which the camera modules 1100a, 1100b and 1100c operate in low powers. The power levels of the camera modules 1100a, 1100b and 1100c may be the same as or different from each other. In addition, the power levels may be changed dynamically or adaptively.

As described above, the pixel array of the image sensor according to example embodiments may increase the full well capacity and at the same time increase the charge overflow barrier between the photoelectric conversion regions in the pixel region, by setting the second thickness of the intra-pixel trench structure being relatively greater than the first thickness of the inter-pixel trench structure.

Example embodiments may be applied to any electronic devices and systems including an image sensor. For example, the example embodiments may be applied to systems such as one or more of a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, an augmented reality (AR) device, a vehicle navigation device, a video phone, a monitoring system, an auto focusing system, a tracking system, a motion detection system, etc.

The foregoing is illustrative of example embodiments and is not to be construed as limiting thereof. Although a few example embodiments have been described, those skilled in the art will readily appreciate that many modifications are possible in the example embodiments without materially departing from the example embodiments.

What is claimed is:

1. A pixel array of an image sensor, comprising:
a substrate comprising an inter-pixel trench structure configured to divide the semiconductor substrate into a plurality of pixel regions, the inter-pixel trench structure comprising first portions extending in a first horizontal direction and second portions extending in a second horizontal direction perpendicular to the first horizontal direction and having a lattice shape when viewed in a vertical direction;
a first photoelectric conversion region and a second photoelectric conversion region in a pixel region of the plurality of pixel regions; and
an intra-pixel trench structure in the pixel region, the intra-pixel trench structure configured to separate the first photoelectric conversion region and the second photoelectric conversion region from each other,
wherein the inter-pixel trench structure has a first thickness, and at least a portion of the intra-pixel trench structure has a second thickness greater than the first thickness.

2. The pixel array of claim 1, wherein the inter-pixel trench structure and the intra-pixel trench structure extend in the vertical direction from a front surface of the semiconductor substrate to a back surface of the semiconductor substrate, and
wherein at least a portion corresponding to a cross region of the intra-pixel trench structure is removed in the vertical direction from the front surface of the semiconductor substrate, such that the intra-pixel trench structure is configured to transfer charges between the first photoelectric conversion region and the second photoelectric conversion region in the cross region.

3. The pixel array of claim 2, wherein an entirety of the intra-pixel trench structure has the second thickness.

4. The pixel array of claim 2, wherein the intra-pixel trench structure has a hammer shape, such that an end portion adjacent to the cross region protrudes to have the second thickness, and a remaining portion excluding the end portion has a thickness smaller than the second thickness.

5. The pixel array of claim 2, wherein the intra-pixel trench structure has a rhombus shape, such that an end portion adjacent to the cross region has the second thickness and a thickness of a remaining portion excluding the end portion decreases as the remaining portion is farther away from the cross region.

6. The pixel array of claim 2, wherein the intra-pixel trench structure extends in the first horizontal direction or the second horizontal direction to divide the pixel region into two equal portions comprising a first sub-pixel region and a second sub-pixel region.

7. The pixel array of claim 6, wherein the cross region is provided in a central portion of the intra-pixel trench structure in the first horizontal direction or the second horizontal direction.

8. The pixel array of claim 6, wherein the cross region is provided adjacent to the inter-pixel trench structure at an end portion of the intra-pixel trench structure in the first horizontal direction or the second horizontal direction.

9. The pixel array of claim 2, wherein the intra-pixel trench structure extends in a diagonal horizontal direction between the first horizontal direction and the second horizontal direction to divide the pixel region into two equal portions comprising a first sub-pixel region and a second sub-pixel region.

10. The pixel array of claim 9, wherein the cross region is provided in a central portion of the intra-pixel trench structure in the diagonal horizontal direction.

11. The pixel array of claim 1, further comprising:
a passivation film surrounding the inter-pixel trench structure and the intra-pixel trench structure.

12. The pixel array of claim 11, wherein the inter-pixel trench structure and the intra-pixel trench structure extend in the vertical direction from a front surface of the semiconductor substrate to a back surface of the semiconductor substrate, and
wherein an entire portion corresponding to a cross region of the intra-pixel trench structure is removed in the vertical direction from the front surface of the semiconductor substrate to the back surface of the semiconductor substrate, such that the intra-pixel trench structure is configured to charges between the first photoelectric conversion region and the second photoelectric conversion region in the cross region.

13. The pixel array of claim 12, wherein a portion of the passivation film extends in the vertical direction from a lower portion of the cross region to the back surface of the semiconductor substrate.

14. The pixel array of claim 1, further comprising:
microlenses arranged one by one per a pixel region of the plurality of pixel regions to perform auto-focusing based on photoelectrons collected respectively in the first photoelectric conversion region and the second photoelectric conversion region.

15. The pixel array of claim 1, wherein the plurality of pixel regions comprise:
one or more first pixel regions in which the intra-pixel trench structure extends in the second horizontal direction to divide the one or more first pixel regions into the two equal portions in the first horizontal direction; and
one or more second pixel regions in which the intra-pixel trench structure extends in the first horizontal direction to divide the one or more second pixel regions into the two equal portions in the second horizontal direction.

16. A pixel array of an image sensor, comprising:
a substrate comprising an inter-pixel trench structure configured to divide the semiconductor substrate into a plurality of pixel regions, the inter-pixel trench structure comprising first portions extending in a first horizontal direction and second portions extending in a second horizontal direction perpendicular to the first horizontal direction and having a lattice shape when viewed in a vertical direction;
a first photoelectric conversion region, a second photoelectric conversion region, a third photoelectric conversion region and a fourth photoelectric conversion region in a pixel region of the plurality of pixel regions; and
an intra-pixel trench structure in the pixel region, the intra-pixel trench structure configured to separate isolate the first photoelectric conversion region, the second photoelectric conversion region, the third photoelectric conversion region and the fourth photoelectric conversion region from each other,
wherein the inter-pixel trench structure has a first thickness, and at least a portion of the intra-pixel trench structure has a second thickness greater than the first thickness.

17. The pixel array of claim 16, wherein the inter-pixel trench structure and the intra-pixel trench structure extend in the vertical direction from a front surface of the semiconductor substrate to a back surface of the semiconductor substrate, and
wherein at least a portion corresponding to a cross region of the intra-pixel trench structure is removed in the vertical direction from the front surface of the semiconductor substrate, such that the intra-pixel trench structure is configured to transfer charges between the first photoelectric conversion region, the second photoelectric conversion region, the third photoelectric conversion region and the fourth photoelectric conversion region in the cross region.

18. The pixel array of claim 17, wherein the intra-pixel trench structure comprises:
a first intra-pixel trench structure extending in the second horizontal direction to divide the pixel region into the two equal portion in the first horizontal direction; and
a second intra-pixel trench structure extending in the first horizontal direction to divide the pixel region into the two equal portions in the second horizontal direction, and
wherein the cross region is provided at a portion where the first intra-pixel trench structure and the second intra-pixel trench structure intersect.

19. The pixel array of claim 17, further comprising:
a floating diffusion region in the cross region,
wherein the floating diffusion region is shared by the first photoelectric conversion region, the second photoelectric conversion region, the third conversion region, and the fourth photoelectric conversion region.

20. A pixel array of an image sensor, comprising:
a substrate comprising an inter-pixel trench structure in a semiconductor to divide the semiconductor substrate into a plurality of pixel regions, the inter-pixel trench structure comprising first portions extending in a first horizontal direction and second portions extending in a second horizontal direction perpendicular to the first horizontal direction and having a lattice shape when viewed in a vertical direction;
a plurality of photoelectric conversion regions in a pixel region of the plurality of pixel regions; and
an intra-pixel trench structure in the pixel region, the intra-pixel trench structure configured to separate the plurality of photoelectric conversion regions from each other,
wherein the inter-pixel trench structure has a first thickness, and at least a portion of the intra-pixel trench structure has a second thickness greater than the first thickness.
